(19) United States
(12) Patent Application Publication
(10) Pub. No.: US 2025/0293690 A1
(43) Pub. Date: Sep. 18, 2025

(54) SEMICONDUCTOR DEVICE AND ELECTRONIC DEVICE INCLUDING SAME

(71) Applicant: ROHM CO., LTD., Kyoto (JP)

(72) Inventor: Takeharu IMAI, Kyoto (JP)

(21) Appl. No.: 19/080,540

(22) Filed: Mar. 14, 2025

(30) Foreign Application Priority Data
Mar. 15, 2024 (JP) 2024-041014

(51) Int. Cl. H03L 1/02; H03L 7/099

(52) U.S. Cl. CPC H03L 1/023; H03L 7/0995

(57) ABSTRACT

A semiconductor device includes: a semiconductor element configured to output a compensation voltage; a constant current circuit configured to output a constant current so as to compensate for temperature dependence according to the comparison of the compensation voltage and a reference voltage; an oscillation circuit configured to output an oscillation signal according to the constant current; a check voltage generation circuit configured to output a check voltage; and a signal generation circuit configured to output a temperature information signal corresponding to the compensation voltage and the check voltage.

### INCORPORATION BY REFERENCE

This nonprovisional application claims priority under 35 U.S.C. § 119(a) on Patent Application No. 2024-041014 filed in Japan on Mar. 15, 2024, the entire contents of which are hereby incorporated by reference.

### BACKGROUND OF THE DISCLOSURE

### Field of the Invention

The present disclosure relates to a semiconductor device and an electronic device which includes the semiconductor device.

### Description of the Related Art

Conventionally, a semiconductor device which includes a charge pump circuit is provided. This semiconductor device generates a write voltage by a step-up operation using a charge pump, and performs data erase and write operations on a nonvolatile memory.

### SUMMARY OF THE DISCLOSURE

A semiconductor device disclosed in the specification includes a semiconductor element, a constant current circuit, an oscillation circuit, a check voltage generation circuit and a signal generating circuit. The semiconductor element is configured to output a compensation voltage corresponding to temperature. The constant current circuit is configured to output a constant current so as to compensate for temperature dependence according to the comparison of the compensation voltage and a reference voltage. The oscillation circuit is configured to output an oscillation signal according to the constant current. The check voltage generation circuit is configured to output a check voltage. The signal generation circuit is configured to output a temperature information signal corresponding to the compensation voltage and the check voltage.

An electronic device disclosed in the specification includes the semiconductor device of the configuration described above.

### DESCRIPTION OF THE DRAWINGS

FIG. 1 is a circuit diagram showing a semiconductor device in a comparative example;

FIG. 2 is a diagram showing a semiconductor device according to the present disclosure;

FIG. 3 is a diagram showing a check voltage generation circuit and an area therearound;

FIG. 4 is a graph showing a relationship between a compensation voltage corresponding to the temperature of a diode and a check voltage;

FIG. 5 is a graph showing a relationship between the compensation voltage corresponding to the temperature of the diode and the check voltage having a plurality of setting values;

FIG. 6 is a diagram showing an error in the result of the comparison of the check voltage and the compensation voltage caused by a process variation;

FIG. 7 is a timing chart showing a control example in which the temperature of the diode is detected by switching the check voltage to a plurality of setting values;

FIG. 8 is a timing chart showing a control example in which the temperature of the diode is detected by switching the check voltage to a plurality of setting values; and

FIG. 9 is a diagram showing values of bit data for detected temperatures.

### DESCRIPTION OF THE PREFERRED EMBODIMENTS

### Detailed Description

A semiconductor device 50 which is a comparative example of a semiconductor device 100 according to the present disclosure will first be described, and then, the semiconductor device 100 according to the present disclosure will be described. The semiconductor device 50 in the comparative example has a basic configuration in common with the semiconductor device 100 according to the present disclosure. Hence, for the semiconductor device 100 according to the present disclosure which will be described later, configurations different from the semiconductor device 50 in the comparative example will be mainly described.

### <Semiconductor Device in Comparative Example>

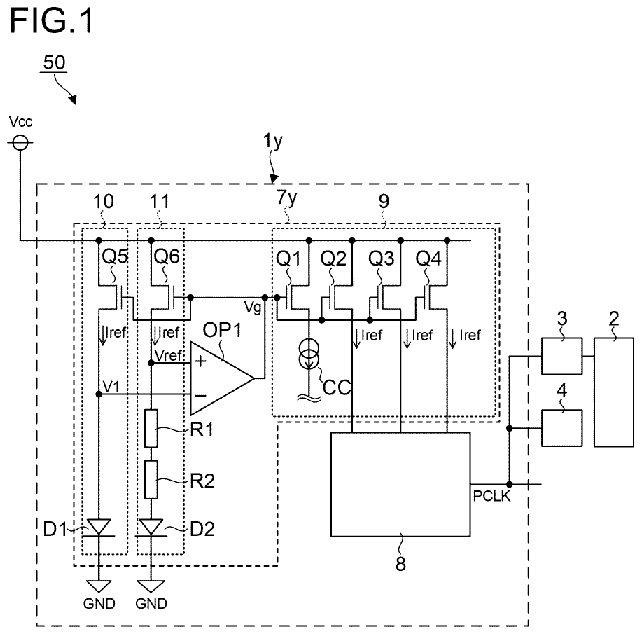

FIG. 1 is a circuit diagram showing the semiconductor device 50. The semiconductor device 50 includes an oscillator circuit 1y, a memory circuit 2, a charge pump circuit 3 and a counter circuit 4.

The oscillator circuit 1y generates a predetermined internal clock signal PCLK, and inputs it to the charge pump circuit 3 and the counter circuit 4.

The memory circuit 2 is a nonvolatile memory which can electrically write and erase information (for example, an EEPROM [Electrically Erasable Programmable Read-Only Memory]).

The charge pump circuit 3 receives an input of the internal clock signal PCLK to output an output voltage Vo obtained by stepping up a power supply voltage Vcc. The charge pump circuit 3 applies the output voltage Vo to a row decoder, a column decoder and a memory cell array (not shown) in the memory circuit 2. The output voltage Vo is applied to the memory circuit 2, and thus information is written in the memory circuit 2.

The counter circuit 4 receives an input of the internal clock signal PCLK to set a write time during which information is written in the memory circuit 2. Information is written in the memory circuit 2 within the write time.

The detailed configuration of the oscillator circuit 1y will be described. As shown in FIG. 1, the oscillator circuit 1y includes a constant current circuit 7y and a ring oscillator 8.

The constant current circuit 7y is a bandgap type current generation circuit which can compensate for temperature dependence. In other words, the constant current circuit 7y is configured to generate a reference current Iref which does not depend on temperature and the power supply voltage (=Vcc). The specific configuration of the constant current circuit 7y is as follows.

The constant current circuit 7y includes a current generation circuit 9, a compensation voltage generation circuit 10, a reference voltage generation circuit 11 and an operational amplifier OP1.

The current generation circuit 9 generates the reference current Iref corresponding to an output voltage Vg and the power supply voltage Vcc, and supplies it to the ring oscillator 8. The compensation voltage generation circuit 10 generates a compensation voltage V1 which is varied according to temperature (more specifically, the temperature of a diode D1 which will be described later). The reference voltage generation circuit 11 generates a predetermined reference voltage Vref. The operational amplifier OP1 generates the output voltage Vg corresponding to a difference voltage between the compensation voltage V1 and the reference voltage Vref. The specific configurations of the compensation voltage generation circuit 10, the reference voltage generation circuit 11 and the current generation circuit 9 are as follows.

The current generation circuit 9 includes a constant current source CC and transistors Q1 to Q4. The constant current source CC outputs a constant current. The constant current source CC generates an output current depending on temperature dependence.

The transistors Q1 to Q4 are P-channel MOSFETs. The gate ends of the transistors Q1 to Q4 are connected to each other to form a common gate. The source ends of the transistors Q1 to Q4 are connected to the application end of the power supply voltage Vcc. The drain end of the transistor Q1 is connected to the constant current source CC. The drain ends of the transistors Q2 to Q4 are connected to the ring oscillator 8 (more specifically, inverter stages configured in the ring oscillator 8).

The compensation voltage generation circuit 10 includes a transistor Q5 and the diode D1.

The transistor Q5 is a P-channel MOSFET (Metal-Oxide-Semiconductor Field-Effect Transistor). The gate end of the transistor Q5 is connected to the common gate of the transistors Q1 to Q4. The source end of the transistor Q5 is connected to the application end of the power supply voltage Vcc. The drain end of the transistor Q5 is connected to the anode of the diode D1 and the inverting input terminal (−) of the operational amplifier OP1.

The reference voltage generation circuit 11 includes a transistor Q6, resistors R1 and R2 and a diode D2.

The transistor Q6 is a P-channel MOSFET. The gate end of the transistor Q6 is connected to the common gate of the transistors Q1 to Q5. The source end of the transistor Q6 is connected to the application end of the power supply voltage Vcc. The drain end of the transistor Q6 is connected to the first end of the resistor R1 and the non-inverting input terminal (+) of the operational amplifier OP1.

The cathode of the diode D1 is connected to a ground end GND. The second end of the resistor R1 is connected to the first end of the resistor R2. The second end of the resistor R2 is connected to the anode of the diode D2. The cathode of the diode D2 is connected to the ground end GND.

The transistors Q1 to Q6 form a so-called current mirror circuit. The transistors Q1 to Q6 generate the reference current Iref which mirrors the output current of the constant current source CC.

The reference current Iref flows through a path extending from the transistor Q5 via the diode D1 toward the ground terminal GND, a path extending from the transistor Q6 via the resistors R1 and R2 and the diode D2 toward the ground end GND and a path extending from the transistors Q2 to Q4 toward the ring oscillator 8.

In this way, the compensation voltage V1 is generated at the connection node of the transistor Q4 and the diode D1. The compensation voltage V1 is the forward voltage of the diode D1. The compensation voltage V1 is varied depending on the temperature of the diode D1.

The reference voltage Vref is generated at the connection node of the transistor Q6 and the resistor R1. The reference voltage Vref is determined from the resistance values of the resistors R1 and R2, the forward voltage of the diode D2 and the reference current Iref.

The output end of the operational amplifier OP1 is connected to the common gate of the transistors Q1 to Q6. The operational amplifier OP1 outputs the output voltage Vg from its output end according to the reference voltage Vref input to the non-inverting input terminal (+) and the compensation voltage V1 input to the inverting input terminal (−).

Here, as described above, the compensation voltage V1 is varied according to the temperature of the diode D1. Hence, the output voltage Vg is also varied according to the variation in the compensation voltage V1. The output voltage Vg is varied, and thus a drive voltage (=the gate-source voltage of each of the transistors Q1 to Q6) which is applied to the common gate of the transistors Q1 to Q6 is changed, with the result that the reference current Iref is also changed. In this way, a constant current circuit 7x supplies the reference current Iref to the ring oscillator 8 while compensating for the temperature dependence of the constant current source CC by the compensation voltage Vg.

The ring oscillator 8 is an oscillation circuit in which a plurality of (here, three) inverter stages are arranged in the shape of a ring so as to form a loop path. The ring oscillator 8 receives the supply of the reference current Iref to generate the internal clock signal PCLK. The oscillation frequency of the internal clock signal PCLK is varied according to the current value of the reference current Iref.

### <Considerations on Temperature Information>

Incidentally, in a semiconductor device such as the semiconductor device 50 described above, various failures (such as a malfunction and damage) may occur due to a change in the internal temperature caused by abnormal heat generation or the like. Hence, in the semiconductor device as described above, there is room for further study regarding the utilization of information on the temperature of the interior of the semiconductor device (hereinafter simply referred to as “temperature information”).

### <About Semiconductor Device 100 According to the Present Disclosure>

The semiconductor device 100 according to the present disclosure will then be described. As described above, the semiconductor device 100 according to the present disclosure has a basic configuration in common with the semiconductor device 50. Hence, configurations in common with the semiconductor device 50 are identified with same symbols, and a part of the description thereof is omitted.

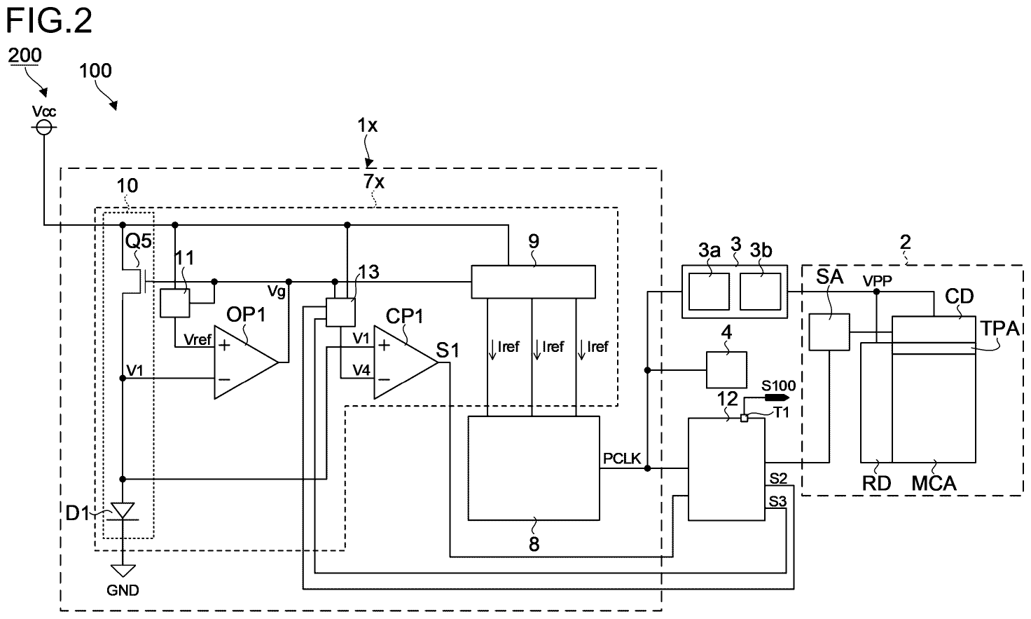

FIG. 2 is a diagram showing the semiconductor device 100 according to the present disclosure. As shown in FIG. 2, the semiconductor device 100 includes a memory circuit 2, a charge pump circuit 3 and a counter circuit 4 which are equivalent to those described previously. In addition to them, the semiconductor device 100 includes an oscillator circuit 1x and a control circuit 12. The semiconductor device 100 can be mounted on an electronic device 200 which is an in-vehicle device.

The memory circuit 2 includes a memory cell array MCA, a trimming parameter area TPA, a row decoder RD, a column decoder CD and a sense amplifier SA.

The trimming parameter area TPA is provided in an extra area of the memory cell array MCA. In the trimming parameter area TPA, predetermined trimming information is stored. The trimming information includes data on a process variation in the diode D1. The details of the trimming information and the process variation will be described later.

The sense amplifier SA captures the trimming information stored in the trimming parameter area TPA via a bit line for the trimming parameter area TPA, and outputs the trimming information to the control circuit 12.

The charge pump circuit 3 receives an input of the internal clock signal PCLK to generate a write voltage VPP for driving the memory circuit 2. The write voltage VPP is applied to the row decoder RD, the column decoder CD and the memory cell array MCA in the memory circuit 2. Specifically, the details thereof are as follows.

The charge pump circuit 3 includes a step-up clock generation circuit 3a and a step-up circuit 3b. The step-up clock generation circuit 3a receives an input of the internal clock signal PCLK to generate a pulse signal having the same phase as the internal clock signal PCLK and a pulse signal having the opposite phase (not shown). The step-up circuit 3b is configured to include a plurality of transistors and a plurality of capacitors (not shown). The step-up circuit 3b steps up the write voltage VPP to a desired voltage value while charging and discharging the capacitors according to the pulse signal having the same phase and the pulse signal having the opposite phase generated by the step-up clock generation circuit 3a.

The oscillator circuit 1x includes a ring oscillator 8 which is equivalent to that described previously. In addition to the ring oscillator 8, the oscillator circuit 1x includes a constant current circuit 7x.

The constant current circuit 7x is a bandgap type current generation circuit which can compensate for temperature dependence. In other words, the constant current circuit 7x is configured to generate a reference current Iref which does not depend on temperature and the power supply voltage (=Vcc). The specific configuration of the constant current circuit 7x is as follows.

The constant current circuit 7x includes a compensation voltage generation circuit 10, a reference voltage generation circuit 11, an operational amplifier OP1 and a current generation circuit 9 which are equivalent to those described previously. In addition to them, the constant current circuit 7x includes a check voltage generation circuit 13 and a comparison circuit CP1.

The check voltage generation circuit 13 receives the supply of the power supply voltage Vcc to generate a predetermined check voltage V4. The specific configuration of the check voltage generation circuit 13 is as follows.

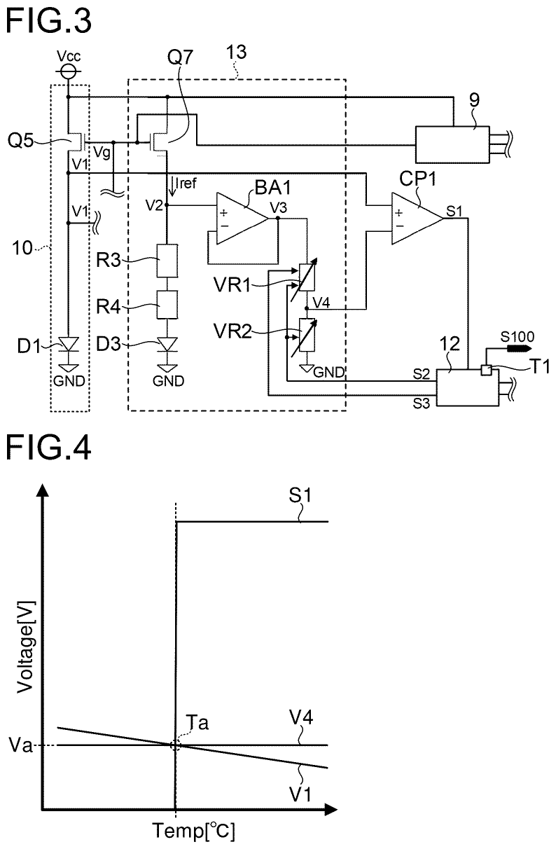

FIG. 3 is a diagram showing the check voltage generation circuit 13 and an area therearound. As shown in FIG. 3, the check voltage generation circuit 13 includes a transistor Q7, resistors R3 and R4, a diode D3, a buffer amplifier BA1 and variable resistors VR1 and VR2.

The transistor Q7 is a P-channel MOSFET. The gate end of the transistor Q7 is connected to the gate end of the transistor Q5 (=common gate of the transistors Q1 to Q6), The source end of the transistor Q7 is connected to the application end of the power supply voltage Vcc. The drain end of the transistor Q7 is connected to the first end of the resistor R3 and the non-inverting input terminal (+) of the buffer amplifier BA1.

The second end of the resistor R3 is connected to the first end of the resistor R4. The second end of the resistor R4 is connected to the anode of the diode D3. The cathode of the diode D3 is connected to the ground end GND.

The output end of the buffer amplifier BA1 is connected to the first end of the variable resistor VR1 and the inverting input terminal (−) of the buffer amplifier BA1 to form a feedback loop.

The second end of the variable resistor VR1 is connected to the first end of the variable resistor VR2 and the inverting input terminal (−) of the comparison circuit CP1. The second end of the variable resistor VR2 is connected to the ground end GND.

The transistor Q7 forms a current mirror circuit together with the transistors Q1 to Q6. In this way, the transistor Q7 generates the reference current Iref which mirrors the output current of the constant current source CC.

The reference current Iref generated by the transistor Q7 flows through a path extending from the transistor Q7 via the resistors R3 and R4 and the diode D3 toward the ground end GND. In this way, a voltage V2 is generated at the connection node of the transistor Q2 and the resistor R1. The voltage V2 is determined from the resistance values of the resistors R3 and R4 and the forward voltage of the diode D3 and the reference current Iref.

In the buffer amplifier BA1, the voltage V2 is input to the non-inverting input terminal (+), and the output end and the inverting input terminal (−) thereof are connected. In this way, the buffer amplifier BA1 performs feedback control on the output voltage V3 such that the voltage V2 matches the output voltage V3 (such that the non-inverting input terminal (+) and the inverting input terminal (−) are imaginarily shorted).

The variable resistors VR1 and VR2 are connected in series as described above. Specifically, the variable resistors VR1 and VR2 function as a voltage divider circuit which divides the output voltage V3 according to a voltage division ratio determined by the resistance values thereof to generate the check voltage V4. The check voltage V4 is generated at the connection node of the variable resistors VR1 and VR2.

The variable resistors VR1 and VR2 are configured to be capable of changing the resistance values thereof by receiving an input of a voltage control signal S2 from the control circuit 12 which will be described later. The variable resistor VR1 is configured to be capable of changing the resistance value thereof by receiving an input of a trimming control signal S3. In other words, the voltage divider circuit of the variable resistors VR1 and VR2 is configured to be capable of controlling the voltage division ratio with the voltage control signal S2 and the trimming control signal S3. Furthermore, in other words, the control circuit 12 is configured to be capable of controlling the voltage value of the check voltage V4 with the voltage control signal S2 and the trimming control signal S3. The details of the configuration of the control circuit 12 and the setting of the check voltage V4 will be described later.

As shown in FIGS. 2 and 3, the comparison circuit CP1 receives an input of the check voltage V4 at the inverting input terminal (−), and receives an input of the compensation voltage V1 at the non-inverting input terminal (+). The comparison circuit CP1 compares the check voltage V4 and the compensation voltage V1 to generate a comparison signal S1 corresponding to the result of the comparison. Specifically, the comparison circuit CP1 compares the check voltage V4 and the compensation voltage V1 to detect whether the check voltage V4 exceeds the compensation voltage V1, and turns the logic level of the comparison signal S1 to a high level (=Vcc reference) or a low level (=GND reference) according to the result of the detection.

The comparison circuit CP1 may be configured to have an internal register and latch (=temporarily store) the result of the detection in the internal register. In this case, the comparison circuit CP1 can reflect the result of the detection latched in the internal register on the comparison signal S1 at any timing.

As shown in FIG. 2, the control circuit 12 receives an input of the internal clock signal PCLK and an input of the comparison signal S1. The control circuit 12 is configured to be capable of accessing the trimming parameter area TPA via the sense amplifier SA.

The control circuit 12 includes an external terminal T1. The control circuit 12 generates an external signal S100 corresponding to the comparison signal S1. The control circuit 12 outputs the external signal S100 via the external terminal T1 to the outside of the apparatus which is not shown. The external signal S100 includes the temperature information of the diode D1 acquired by temperature detection control which will be described later.

The control circuit 12 generates the voltage control signal S2, the trimming control signal S3 and the external signal S100. The control circuit 12 performs various types of internal control. The types of control performed by the control circuit 12 will be described in detail.

### <Acquisition of Temperature Information>

The control circuit 12 acquires the temperature information based on the comparison signal S1. Specifically, the details thereof are as follows. As described previously, the comparison signal S1 is a signal which corresponds to the result of the comparison of the compensation voltage V1 and the check voltage V4. As described previously, the compensation voltage V1 is the forward voltage of the diode D1. In other words, the voltage value of the compensation voltage V1 is varied according to the temperature of the diode D1 and the temperature characteristic of the diode D1. Hence, the comparison signal S1 indicates whether the temperature of the diode D1 (which corresponds to the voltage value of the compensation voltage V1) exceeds a predetermined temperature (which corresponds to the voltage value of the check voltage V4). Therefore, the control circuit 12 can detect the temperature of the diode D1, and hence, the temperature information of the interior of the semiconductor device 100 by receiving an input of the comparison signal S1. Specifically, the details thereof are as follows.

FIG. 4 is a graph showing a relationship between the compensation voltage V1 corresponding to the temperature of the diode D1 and the check voltage V4. As shown in FIG. 4, the diode D1 has a negative voltage characteristic with respect to temperature. In other words, the compensation voltage V1 has a voltage characteristic in which the voltage is decreased as the temperature is increased (toward the right side of the graph in FIG. 4).

Here, as shown in FIG. 4, the voltage value of the check voltage V4 is assumed to be set to a predetermined first setting value Va. The forward voltage (=compensation voltage V1) of the diode D1 is set to match the voltage value of the first setting value Va at a predetermined first temperature Ta.

As shown in FIG. 4, when the compensation voltage V1 exceeds the check voltage V4, the comparison signal S1 is low, and when the compensation voltage V1 falls below the check voltage V4, the comparison signal S1 is high. The control circuit 12 receives an input of the comparison signal S1 to be able to detect whether the temperature of the diode D1 exceeds the first temperature Ta.

### <About Detection of Arbitrary Temperature>

As described above, the resistance values of the variable resistors VR1 and VR2 are changed, and thus the check voltage V4 can be changed to an arbitrary voltage value. Hence, the control circuit 12 can detect whether the voltage value of the compensation voltage V1 exceeds the arbitrary voltage value, that is whether the temperature of the diode D1 exceeds an arbitrary temperature. Specifically, the details thereof are as follows.

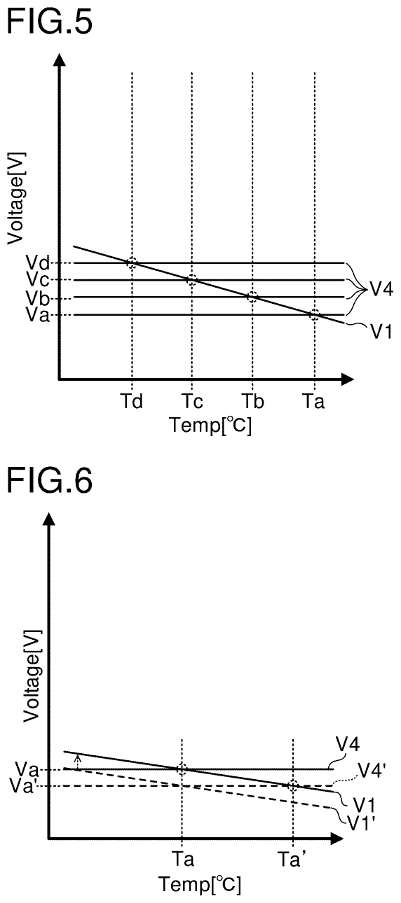

FIG. 5 is a graph showing a relationship between the compensation voltage V1 corresponding to the temperature of the diode D1 and the check voltage V4 having a plurality of setting values. As shown in FIG. 5, the voltage value of the check voltage V4 can be set to not only the first setting value Va described above but also one of four setting values, that is, a second setting value Vb, a third setting value Vc or a fourth setting value Vd.

The control circuit 12 can change the voltage value of the check voltage V4 to one of the first to fourth setting values Va to Vd with the voltage control signal S2. In this way, the control circuit 12 individually compares the compensation voltage V1 with each of the first to fourth setting values Va to Vd, and thereby can acquire the results of the comparisons. The control circuit 12 can acquire, from the results of the comparisons obtained, an approximate value of the temperature of the diode D1.

For example, as described above, when the voltage value of the check voltage V4 is set to the first setting value Va, whether the temperature of the diode D1 exceeds the first temperature Ta is detected. The voltage value of the check voltage V4 is changed to the second setting value Vb, and thus whether the temperature of the diode D1 exceeds a second temperature Tb (=temperature corresponding to the second setting value Vb based on the temperature characteristic of the diode D1) is detected. The second setting value Vb is higher in voltage value than the first setting value Va. Hence, the timing at which the compensation voltage V1 falls below the second setting value Vb is earlier than the timing at which the compensation voltage V1 falls below the first setting value Va. Therefore, it is possible to detect whether the temperature of the diode D1 exceeds the second temperature Tb which is lower than the first temperature Ta.

Likewise, the voltage value of the check voltage V4 is changed to the third setting value Vc which is higher than the second setting value Vb, and thus it is possible to detect whether the temperature of the diode D1 exceeds a third temperature Tc which is lower than the second temperature Tb. Moreover, the voltage value of the check voltage V4 is changed to the fourth setting value Vd which is higher than the third setting value Vc, and thus it is possible to detect whether the temperature of the diode D1 exceeds a fourth temperature Td which is lower than the third temperature Tc.

The control circuit 12 receives, while changing the check voltage V4 to each of the first to fourth setting values Va to Vd in any order, an input of the comparison signal S1 to individually acquire the results of the detections. The control circuit 12 can detect, from the results of the detections, that the temperature of the diode D1 is equal to or greater than the first temperature Ta, is less than the first temperature Ta and equal to or greater than the second temperature Tb, is less than the second temperature Tb and equal to or greater than the third temperature Tc, is less than the third temperature Tc and equal to or greater than the fourth temperature Td or is less than the fourth temperature Td.

### <About Control of Resistance Trimming Correction Function>

The semiconductor device 100 has a resistance trimming correction function. The control circuit 12 controls the interior of the semiconductor device 100 when the resistance trimming correction function is performed. The resistance trimming correction function will be described in detail.

The diode D1 has a process variation on an individual basis (=a variation in the temperature characteristic on an individual basis caused in a manufacturing process). Hence, when the resistance trimming correction function described here is not performed, the temperature information of the diode D1 acquired by the control circuit 12 may deviate from the true temperature information due to the process variation possessed by the diode D1. Specifically, the details thereof are as follows.

As described previously, the control circuit 12 receives an input of the comparison signal S1 to acquire the temperature information of the diode D1. Here, when the compensation voltage V1 exceeds the first setting value Va of the check voltage V4, the temperature information acquired by the control circuit 12 indicates that the temperature of the diode D1 is lower than the first temperature Ta. However, when the process variation of the diode D1 described above is relatively large, the compensation voltage V1 is significantly increased or decreased by the process variation, and thus the result of the comparison of the compensation voltage V1 and the check voltage V4 deviates from the true temperature information of the diode D1. Specifically, the details thereof are as follows.

FIG. 6 is a diagram showing an error in the result of the comparison of the check voltage V4 and the compensation voltage V1 caused by the process variation. In FIG. 6, the compensation voltage V1 including the process variation which increases the voltage value is indicated by a solid line. In the figure, the compensation voltage V1 in an ideal state with no consideration given to the process variation is indicated as a compensation voltage V1′ by a dashed line. In the figure, the check voltage V4 on which trimming correction has been performed is indicted by a solid line. In the figure, the check voltage V4 on which the trimming correction is not performed is indicted as a check voltage V4′ by a dotted line. The first setting value Va when the trimming correction is not performed is indicted as a first setting value Va′ by a dotted line.

As shown in FIG. 6, in a case where the compensation voltage V1 is increased by the process variation, when the trimming correction is not performed, though the temperature of the diode D1 actually exceeds the first temperature Ta, the compensation voltage V1 does not fall below the check voltage V4′ until the temperature of the diode D1 reaches a temperature Ta′ higher than the first temperature Ta. In other words, when the temperature of the diode D1 is between the first temperature Ta and the temperature Ta′, the control circuit 12 acquires erroneous temperature information indicating that the temperature of the diode D1 does not exceed the first temperature Ta.

By contrast, when the compensation voltage V1 is decreased by the process variation, though the temperature of the diode D1 is actually lower than the first temperature Ta, the compensation voltage V1 may fall below the check voltage V4 (not shown). In this case, the control circuit 12 acquires erroneous temperature information indicating that the temperature of the diode D1 exceeds the first temperature Ta.

Hence, the semiconductor device 100 performs the trimming correction function to suppress a variation in the compensation voltage V1 caused by the process variation, and thereby enhances the accuracy of the temperature information. Specifically, the details thereof are as follows.

The control circuit 12 corrects the voltage value of the check voltage V4 to reduce the process variation in the diode D1. Specifically, when the compensation voltage V1 is increased by the process variation, the control circuit 12 corrects the voltage value of the check voltage V4 to increase the voltage value of the check voltage V4 by an amount corresponding to the process variation (which corresponds to a difference between V1 and V1′ shown in FIG. 6). By contrast, when the compensation voltage V1 is decreased by the process variation, the control circuit 12 corrects the voltage value of the check voltage V4 to lower the voltage value of the check voltage V4 by an amount corresponding to the process variation.

The control circuit 12 acquires the trimming information (the process variation possessed by the diode D1) via the sense amplifier SA. Then, the control circuit 12 generates the trimming control signal S3 based on the acquired trimming information to correct the voltage value of the check voltage V4 as described above.

As shown in FIG. 6, the trimming correction is performed, and thus the voltage value of the check voltage V4 is increased from the first setting value Va′ to the first setting value Va to reduce the process variation of the diode D1. Hence, the temperature when the compensation voltage V1 falls below the check voltage V4 is corrected from the temperature Ta′ to the first temperature Ta. In this way, the deviation from the true temperature information as described above is reduced.

### <About Control for Preparing a Plurality of Setting Values for Check Voltage V4 to Perform Temperature Detection>

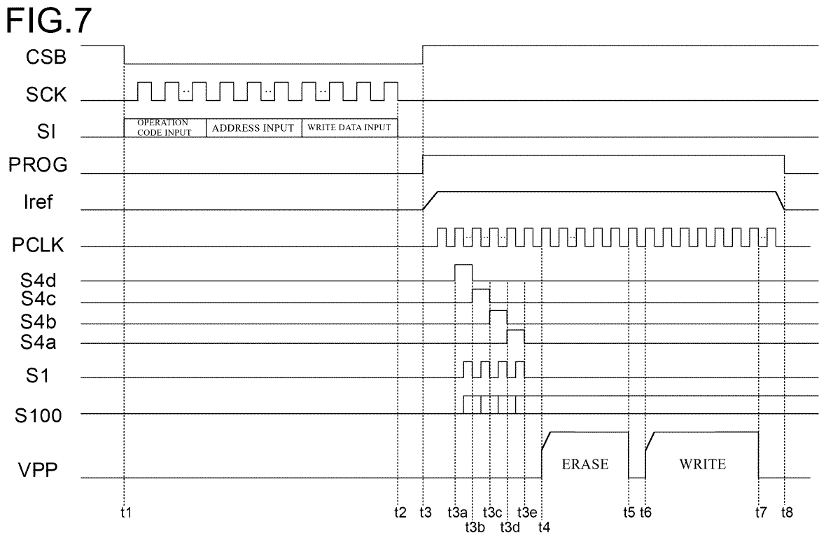

Control when a plurality of setting values for the check voltage V4 described above are changed, and thus temperature detection is performed will then be described in detail. FIG. 7 is a timing chart showing a control example in which the temperature of the diode D1 is detected by switching the check voltage to a plurality of setting values. FIG. 7 shows, sequentially from above, a chip select signal CSB, a clock signal SCK, serial input data SI, a program signal PROG, the current value of the reference current Iref, the internal clock signal PCLK, the voltage control signal S2, the comparison signal S1, the external signal S100 and the write voltage VPP.

When the chip select signal CSB falls to a low level at time t1, a series of write control steps on the memory circuit 2 are started. Specifically, the clock signal SCK for serial communication with the memory circuit 2 is pulse-driven at a predetermined period. In this way, the serial input data SI (=a predetermined data bit group which is input by serial communication to the memory circuit 2) is input in the order of an operation code, a write destination address and write data.

When time t2 arrives, the pulse driving of the clock signal SCK is stopped, and the input of the serial input data SI is also completed. Thereafter, the chip select signal CSB rises to a high level at time t3.

At time t3, the program signal PROG rises from a low level to a high level. The program signal PROG can be said to be an enable signal for switching the oscillator circuit 1x between an enabled state (driven state) and a disabled state (undriven state) (not shown). The program signal PROG rises to a high level, and thus the oscillator circuit 1x is brought into the driven state, with the result that the reference current Iref is generated. Then, the internal clock signal PCLK starts to be pulse-driven.

Then, during a period from time t4 to time t5 after a predetermined time has elapsed, the write voltage VPP is applied to the row decoder RD, the column decoder CD and the memory cell array MCA in the memory circuit 2, and thus data is erased (deleted) from the memory circuit 2. Likewise, the write voltage VPP is applied during a period from time t6 to time t7, and thus data is written in the memory circuit 2.

When time t8 arrives, the program signal PROG falls to a low level, and thus the oscillator circuit 1x is brought into the disabled state. In this way, the generation of the reference current Iref is completed, and thus the pulse driving of the internal clock signal PCLK is stopped.

Here, the control for detecting the temperature of the diode D1 described above is performed between time t3 and time t4. Specifically, the details thereof are as follows.

Here, an example will be described where four types of detected temperatures, that is, the first to fourth temperatures Ta to Td are set, and the actual temperature of the diode D1 is higher than the first temperature Ta. As the voltage control signal S2 described above, a voltage control signal S2a for setting of the first temperature Ta, a voltage control signal S2b for setting of the second temperature Tb, a voltage control signal S2c for setting of the third temperature Tc and a voltage control signal S2d for setting of the fourth temperature are indicated. The voltage control signals S2a to S2d are input to at least one of the variable resistors VR1 and VR2 in synchronization with the internal clock signal PCLK to vary the resistance values of the variable resistors VR1 and VR2.

At time t3a when a predetermined time has elapsed from time t3, the voltage control signal S2d rises to a high level. Then, the check voltage V4 is set to the fourth setting value Vd (not shown). Then, the comparison circuit CP1 latches (=temporarily stores) the result of the comparison of the compensation voltage V1 and the fourth setting value Vd in an internal resister. Then, at a timing at which the subsequent pulse of the internal clock signal PCLK falls from time t3a, the comparison signal S1 is turned to a logic level (here, a high level) corresponding to the result of the detection.

Thereafter, when time t3b arrives, the voltage control signal S2d falls to a low level, and the voltage control signal S2c rises to a high level. In this way, the check voltage V4 is set to the third setting value Vc (not shown). Then, the comparison circuit CP1 latches the result of the comparison of the compensation voltage V1 and the third setting value Vc in the internal register. Then, at a timing at which the subsequent pulse of the internal clock signal PCLK falls from time t3b, the comparison signal S1 is turned to a logic level (here, a high level) corresponding to the result of the detection.

Thereafter, when time t3c arrives, the voltage control signal S2c falls to a low level, and the voltage control signal S2b rises to a high level. In this way, the check voltage V4 is set to the second setting value Vb (not shown). Then, the comparison circuit CP1 latches the result of the comparison of the compensation voltage V1 and the second setting value Vb in the internal register. Then, at a timing at which the subsequent pulse of the internal clock signal PCLK falls from time t3c, the comparison signal S1 is turned to a logic level (here, a high level) corresponding to the result of the detection.

Thereafter, when time t3d arrives, the voltage control signal S2b falls to a low level, and the voltage control signal S2a rises to a high level. In this way, the check voltage V4 is set to the first setting value Va (not shown). Then, the comparison circuit CP1 latches the result of the comparison of the compensation voltage V1 and the first setting value Va in the internal register. Then, at a timing at which the subsequent pulse of the internal clock signal PCLK falls from time t3d, the comparison signal S1 is turned to a logic level (here, a high level) corresponding to the result of the detection.

Then, when time t3e arrives, the voltage control signal S2a falls to a low level, and the control for detecting the temperature of the diode D1 is completed. If a larger number of setting values for the check voltage V4 are prepared, after time t3e described above, the control between time t3a and time t3d is repeated.

After time t3a (more specifically, a timing at which the result of the comparison latched by the comparison circuit CP1 is reflected on the comparison signal S1), the control circuit 12 starts the generation and the output of the external signal S100 including the temperature information of the diode D1 according to the comparison signal S1 which has been input. Specifically, the control circuit 12 generates the external signal S100 such that the external signal S100 includes a digital value obtained by decoding the comparison signal S1.

The external signal S100 is output by time t4 when control for writing data in the memory circuit 2 is started. Specifically, the external signal S100 may be output as necessary by receiving the comparison signal S1 between time t3a and time t4 or the external signal S100 which includes all the temperature information included in the comparison signal S1 received between time ta and time te may be output at any timing between time t3e when the temperature detection control is completed and time t4.

### <About Output of Temperature Information>

In addition to the configuration described above, the memory circuit 2 is configured to be able to execute a read status register command when the program signal PROG is high. When the memory circuit 2 executes the read status register command, the memory circuit 2 outputs seral output data SO including the information of a status register in the memory circuit 2.

The control circuit 12 receives an input of the seral output data SO. The control circuit 12 can include, in the seral output data SO, the temperature information generated by decoding the comparison signal S1 to output the resulting data as the external signal S100. Specifically, the details thereof are as follows.

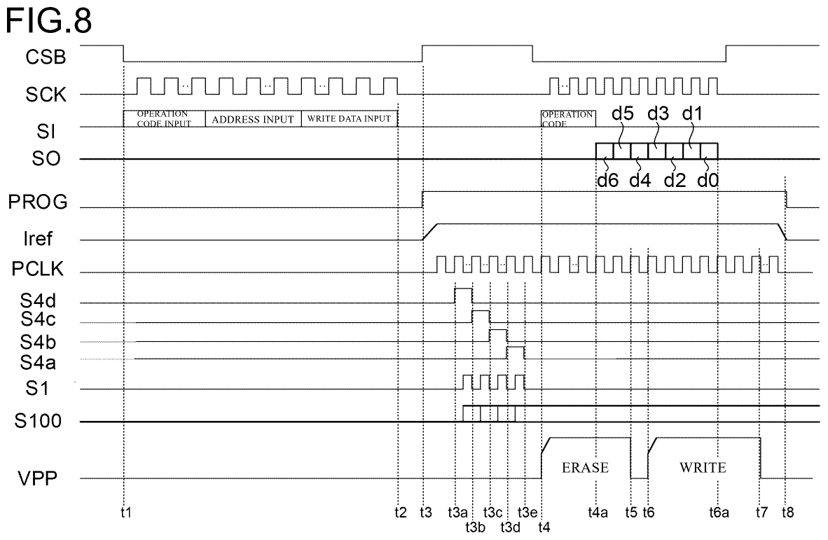

FIG. 8 is a timing chart showing a control example in which the temperature of the diode D1 is detected by switching the check voltage V4 to a plurality of setting values. FIG. 8 shows, sequentially from above, the chip select signal CSB, the clock signal SCK, the serial input data SI, the seral output data SO, the program signal PROG, the current value of the reference current Iref, the internal clock signal PCLK, the voltage control signal S2, the comparison signal S1, the external signal S100 and the write voltage VPP.

Times t1 to t8 in FIG. 8 correspond to times t1 to t8 in FIG. 7. In other words, during times t1 to t8 in FIG. 8, the control described with reference to FIG. 7 is performed, and the subsequent control is further performed.

When the control for detecting the temperature of the diode D1 is completed at time t3e, then at a timing at which the internal clock signal PCLK falls to a low level, the read register command described above is executed. Here, the chip select signal CSB first falls to a low level. Then, at time t4, as the serial input data SI, an operation code indicating the read register command is input. In this way, the pulse driving of the clock signal SCK is started.

Thereafter, at time t4 when the input of the operation code is completed, the seral output data SO is output. The seral output data SO is an 8-bit digital signal. In the seral output data SO, predetermined pieces of register data in the memory circuit 2 are assigned to bits (in FIG. 8, bit data d0 to d6). The seral output data SO is sequentially output from an output end (not shown) for the serial communication in synchronization with the clock signal SCK on a bit-by-bit basis.

The bit data d0 to d6 includes unused bit data (in the figure, the bit data d4 to d6) which is surplus and is not used in a normal read register command. The output data is not assigned to the unused bit data. Hence, since the unused bit data is originally assumed not to have any special meaning, a value of 0 is stored in the unused bit data.

When the control circuit 12 receives an input of the seral output data SO, the control circuit 12 stores the detection temperature information of the diode D1 detected after time t3a (=high/low level digital values indicating whether each of the first to fourth setting values Va to Vd has been exceeded), and outputs the external signal S100 including the seral output data SO to the outside.

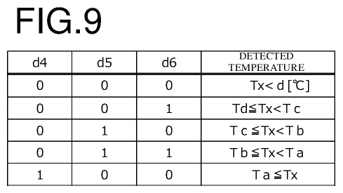

Specifically, the details thereof are as shown in FIG. 9. In FIG. 9, the detected temperature of the diode D1 acquired by the control circuit 12 is represented by Tx. As shown in FIG. 9, when the detected temperature Tx is less than the fourth temperature Td, the bit data d4 to d6 is set to 0. When the detected temperature Tx is equal to or greater than the fourth temperature Td and less than the third temperature Tc, the bit data d4 and d5 is set to 0, and the bit data d5 is set to 1. When the detected temperature Tx is equal to or greater than the third temperature Tc and less than the second temperature Tb, the bit data d4 and d6 is set to 0, and the bit data d5 is set to 1. When the detected temperature Tx is equal to or greater than the second temperature Tb and less than the first temperature Ta, the bit data d4 is set to 0, and the bit data d5 and d6 is set to 1. When the detected temperature Tx is equal to or greater than the first temperature Ta, the bit data d4 is set to 1, and the bit data d5 and d6 is set to 0.

When the detected temperature Tx exceeds the predetermined temperature, the control circuit 12 outputs an alert according to values stored in the bit data d4 to d6. The alert may be included in the external signal S100 or may be a separate external signal.

As described above, the semiconductor device 100 can detect the internal temperature. In this way, it is possible to suppress an erroneous operation caused by heat generation and the occurrence of a failure such as damage. Furthermore, for the temperature detection, the temperature compensation diode D1 included in the bandgap type constant current circuit 7x is used. Hence, a sensor, an element or the like for temperature detection does not need to be provided additionally. Therefore, it is possible to detect the temperature of the interior of the semiconductor device 100 without increasing the number of components in the semiconductor device 100.

As described above, the control circuit 12 can output the detected temperature information as the external signal S100. Hence, the semiconductor device 100 is incorporated in an existing system or the like, and thus the temperature information can be utilized on the side of the system without the additional use of a temperature detection device or the like. In this way, it is possible to suppress an increase in the cost of the entire system, and to reduce the size of the entire system.

As described above, the external signal S100 is output by a timing at which the control for writing data in the memory circuit 2 is started (in FIG. 7, time t4). Hence, even if the temperature of the diode D1 is abnormal, the temperature information of the diode D1 can be output to the system where the semiconductor device 100 is incorporated by the time when the control for writing data in the memory circuit 2 is started. Therefore, it is possible to stop the operation of writing data in the memory circuit 2 according to the temperature information of the semiconductor device 100. In this way, it is possible to suppress the occurrence of a failure in the writing of data in the memory circuit 2.

As described above, the voltage control signals S2a to S2d are input to at least one of the variable resistors VR1 and VR2 in synchronization with the internal clock signal PCLK. Here, while data is being written in the memory circuit 2 (more specifically, when the program signal PROG is high), the control circuit 12 cannot acquire the clock signal from an external terminal (a terminal other than the external terminal T1 which is not shown). However, using the internal clock signal PCLK (in synchronization with the internal clock signal PCLK), the voltage control signals S2a to S2d can be input to the variable resistors VR1 and VR2. Hence, even though the operation of writing data in the memory circuit 2 is being performed, the voltage value of the check voltage V4 can be changed.

The present invention is not limited to the embodiment described above, and various changes can be made without departing from the spirit of the present invention.

### ADDITIONAL notes

A semiconductor device (100) disclosed in the specification includes: a semiconductor element (D1) configured to output a compensation voltage (V1) corresponding to temperature; a constant current circuit (9) configured to output a constant current (Iref) so as to compensate for temperature dependence according to the comparison of the compensation voltage (V1) and a reference voltage (Vref); an oscillation circuit (8) configured to output an oscillation signal (PCLK) according to the constant current (Iref); a check voltage generation circuit (13) configured to output a check voltage (V4); and a signal generation circuit (CP1) configured to output a temperature information signal (S1) corresponding to the compensation voltage (V1) and the check voltage (V4) (first configuration).

In the semiconductor device (100) of the first configuration, the check voltage generation circuit (13) may be configured to be capable of changing the voltage value of the check voltage (V4), and the signal generation circuit (CP1) may generate, for the voltage value of the check voltage (V4) that has been changed, the temperature information signal (S1) according to the result of the comparison with the compensation voltage (V1) (second configuration).

The semiconductor device (100) of the second configuration, may further include: a control circuit (12) configured to receive an input of the temperature information signal (S1) and to input a control signal (S2, S3) to the check voltage generation circuit (13), and the check voltage generation circuit (13) may be configured to be capable of changing the voltage value of the check voltage (V4) according to the control signal (S2, S3) (third configuration).

In the semiconductor device (100) of the third configuration, the check voltage generation circuit (13) may include a resistor (VR1, VR2), and generate the check voltage (V4) according to the constant current (Iref) and the resistance value of the resistor (VR1, VR2), and the control circuit (12) may generate the control signal (S2, S3) to variably control the resistance value of the resistor (VR1, VR2) (fourth configuration).

The semiconductor device (100) of the third or fourth configuration, may further include: a nonvolatile memory (2) configured to store trimming information corresponding to the semiconductor element (D1), and the control circuit (12) may generate the control signal (S3) corresponding to the trimming information stored in the nonvolatile memory (2) to change the voltage value of the check voltage (V4) (fifth configuration).

The semiconductor device (100) of the fifth configuration, may further include: a charge pump circuit (3) configured to receive an input of the oscillation signal (PCLK) to generate a stepped-up voltage (VPP), the stepped-up voltage (VPP) may be applied to the nonvolatile memory (2) such that dada is written in the nonvolatile memory (VPP) and the control circuit (12) may generate an external signal (S100) corresponding to the temperature information signal (S1), and output the external signal (S100) to the outside before the stepped-up voltage (VPP) is applied to the nonvolatile memory (2) such that the dada is written in the nonvolatile memory (2) (sixth configuration).

In the semiconductor device (100) of the sixth configuration, the control circuit (12) may output, while an operation of writing the data in the nonvolatile memory (2) is being performed, the control signal (S2, S3) in synchronization with the oscillation signal (PCLK) to change the voltage value of the check voltage (V4) (seventh configuration).

In the semiconductor device (100) of the sixth or seventh configuration, the control circuit (12) may include an output terminal (T1) configured to output the external signal (S100) (eighth configuration).

An electronic device (200) disclosed in the specification includes: the semiconductor device (100) according to any one of the first to eighth configurations (ninth configuration).

What is claimed is:

1. A semiconductor device comprising:
a semiconductor element configured to output a compensation voltage corresponding to temperature;
a constant current circuit configured to output a constant current so as to compensate for temperature dependence according to a comparison of the compensation voltage and a reference voltage;
an oscillation circuit configured to output an oscillation signal according to the constant current;
a check voltage generation circuit configured to output a check voltage; and
a signal generation circuit configured to output a temperature information signal corresponding to the compensation voltage and the check voltage.

2. The semiconductor device according to claim 1,
wherein the check voltage generation circuit is configured to be capable of changing a voltage value of the check voltage, and
the signal generation circuit generates, for the voltage value of the check voltage that has been changed, the temperature information signal according to a result of the comparison with the compensation voltage.

3. The semiconductor device according to claim 2, further comprising:
a control circuit configured to receive an input of the temperature information signal and to input a control signal to the check voltage generation circuit,
wherein the check voltage generation circuit is configured to be capable of changing the voltage value of the check voltage according to the control signal.

4. The semiconductor device according to claim 3,
wherein the check voltage generation circuit includes a resistor, and generates the check voltage according to the constant current and a resistance value of the resistor, and
the control circuit generates the control signal to variably control the resistance value of the resistor.

5. The semiconductor device according to claim 3, further comprising:
a nonvolatile memory configured to store trimming information corresponding to the semiconductor element,
wherein the control circuit generates the control signal corresponding to the trimming information stored in the nonvolatile memory to change the voltage value of the check voltage.

6. The semiconductor device according to claim 5, further comprising:
a charge pump circuit configured to receive an input of the oscillation signal to generate a stepped-up voltage,
wherein the stepped-up voltage is applied to the nonvolatile memory such that dada is written in the nonvolatile memory, and
the control circuit generates an external signal corresponding to the temperature information signal, and outputs the external signal to an outside before the stepped-up voltage is applied to the nonvolatile memory such that the dada is written in the nonvolatile memory.

7. The semiconductor device according to claim 6,
wherein the control circuit outputs, while an operation of writing the data in the nonvolatile memory is being performed, the control signal in synchronization with the oscillation signal to change the voltage value of the check voltage.

8. The semiconductor device according to claim 6,
wherein the control circuit includes an output terminal configured to output the external signal.

9. An electronic device comprising:
the semiconductor device according to claim 1.
